(19) United States
(12) Patent Application Publication
(10) Pub. No.: US 2013/0298984 A1
(43) Pub. Date: Nov. 14, 2013

(54) PASSIVATION OF SILICON SURFACES USING INTERMEDIATE ULTRA-THIN SILICON OXIDE LAYER AND OUTER PASSIVATING DIELECTRIC LAYER

(71) Applicants: Nazir Pyarali KHERANI, Toronto (CA); A. K. M. Zahidur Rahim CHOWDHURY, Toronto (CA)

(72) Inventors: Nazir Pyarali KHERANI, Toronto (CA); A. K. M. Zahidur Rahim CHOWDHURY, Toronto (CA)

(21) Appl. No.: 13/829,206

(22) Filed: Mar. 14, 2013

Related U.S. Application Data
(60) Provisional application No. 61/646,085, filed on May 11, 2012.

(51) Int. Cl. H01L 21/02; H01L 31/0216; H01L 29/16

(52) U.S. Cl. CPC H01L 21/02592; H01L 29/16; H01L 31/02167
USPC 136/256; 438/479; 257/51; 136/261

(57) ABSTRACT

Methods, structures and devices are provided in which a crystalline silicon surface is passivated by an ultra-thin silicon oxide layer and an outer passivating dielectric layer, where the ultra-thin silicon oxide layer has a thickness on an Angstrom scale. In some embodiments, both layers are formed by low temperature processes. The outer passivating layer may be formed according to a PECVD process that employs hydrogen-containing precursor gases, such that hydrogen is incorporated into one or both of the silicon oxide layer and the passivating dielectric layer. The present methods may be employed for the passivation of a wide variety of structures and devices, including photovoltaic cells, MOSFET devices, flash memory devices, and thin-film silicon substrates that may contain such devices.

### CROSS-REFERENCE TO RELATED APPLICATION

This application claims priority to U.S. Provisional Application No. 61/646,085, titled “PASSIVATION OF SILICON SURFACES USING INTERMEDIATE ULTRA-THIN SILICON OXIDE LAYER AND OUTER PASSIVATING DIELECTRIC LAYER” and filed on May 11, 2012, the entire contents of which is incorporated herein by reference.

### BACKGROUND

The present disclosure relates to silicon surface passivation. More particularly, the present disclosure relates to electronic and optoelectronic devices with passivated silicon surfaces or interfaces.

The performance of many semiconductor electronic and opto-electronic devices is often inversely related to the density of surface states, which are caused by dangling bonds and defects at a surface or interfacial layer. Thermal oxide layers grown at high temperature (>900° C.) are known to cause passivation of such surface states, reducing their density and thereby improving device performance.

The passivation of crystalline silicon (cSi) surfaces by high temperature thermal processing was initially reported by Atalla et al. [1]. The first successful insulated-gate field-effect transistor (FET) utilizing an oxide passivation scheme was fabricated by Kahng et al. [2]. The reduced defect density at the interface between the silicon and its oxide in a sandwich including layers of metal, oxide, and semiconductor (e.g. silicon) (MOS) has made the MOS field transistor (MOSFET), also known as MOS, a widely used semiconductor device. Thermal oxide is also used as an insulator layer for Flash memory semiconductor device which is a MOSFET structure with an additional float gate [26].

Unfortunately, conventional high process temperatures that are employed for the passivation of semiconductor surfaces are incompatible with the production of some high density devices. In particular, as semiconductor devices are scaled down to smaller dimensions, the induced variation in device parameters due to high temperature processing can severely affect the device performance. For example, high-temperature oxidation changes the impurity profiles previously formed in the substrate. Moreover, high stress in oxide films caused by the difference in the thermal expansion of Si and other films causes wafer bending, film cracking, and defect formation in the underlying Si. Accordingly, low-temperature semiconductor device fabrication techniques are needed to prevent such problems.

The formation of silicon gate oxide films using processes which depart from the ‘standard thermal oxidation’ process has been reported. Non-standard thermal oxidation processes, applied on wafers with standard thicknesses, include using a variety of methods such as sputter deposition [3, 4], silicon oxidation in an oxygen plasma [5], thermal oxidation [6], chemical vapor deposition [7], and high-precision-controlled ion assisted process [8]. These techniques, while resulting in interfaces of practical quality, invariably require the use of high temperature treatments or/and are complicated processes.

Surface passivation of cSi is also important for photovoltaic (PV) solar cells in which silicon is used as an absorbing layer. Thermal oxide grown using high temperature processing has been used to fabricate PV solar cells yielding the highest efficiency [9]. Alternative low temperature passivation schemes such as deposition of hydrogenated amorphous silicon (aSi:H) [10, 11], plasma enhanced chemical vapour deposition (PECVD) of silicon oxide (SiOₓ) [12, 13], PECVD silicon nitride (SiNₓ) [12, 13, 14, 15, 16] and PECVD silicon carbide (SiCₓ) [17], have been reported as potential passivation processes for crystalline silicon (cSi) surface.

Among these passivation schemes, PECVD SiNₓ has been studied extensively. Stoichiometric SiNₓ is deemed more suitable owing to its lower absorption in the UV region compared to silicon rich SiNₓ. Further, stoichiometric SiNₓ has better chemical etching selectivity against cSi than silicon rich SiNₓ [15], which is desirable where selective etching of SiNₓ is necessary for device fabrication. High values of fixed positive charge density, Qₛ, at the cSi-SiNₓ interface leads to field effect passivation in the case of nearly stoichiometric SiNₓ. Charge densities of more than 10¹² cm⁻² have been reported [18, 19]. Unfortunately, an induced inversion layer due to the high trapped charge density can lead to parasitic shunting which reduces the short circuit current [20].

Studies have reported the inclusion of a layer of SiO₂ having a thickness on the order of ten nanometers which has been provided between the cSi surface and the SiNₓ layer, wherein the silicon oxide layer is thermally-grown using high-temperature, [21, 22, 23, 24], in order to reduce or remove the aforementioned parasitic effect. Passivation using thermal oxide (10 nm thick) and SiNₓ has been reported, with a surface recombination velocity (SRV) of 10 cm/s [21, 22, 23]. Moreover, an SRV of 6 cm/s [19] has been reported for the PECVD oxide (50 nm thick) and SiNₓ passivation scheme.

### SUMMARY

Methods, structures and devices are provided in which a crystalline silicon surface is passivated by an ultra-thin silicon oxide layer and an outer passivating dielectric layer, where the ultra-thin silicon oxide layer has a thickness on an Angstrom scale. In some embodiments, both layers are formed by low temperature processes. The outer passivating layer may be formed according to a PECVD process that employs hydrogen-containing precursor gases, such that hydrogen is incorporated into one or both of the silicon oxide layer and the passivating dielectric layer. The present methods may be employed for the passivation of a wide variety of structures and devices, including photovoltaic cells, MOSFET devices, flash memory devices, and thin-film silicon substrates that may contain such devices.

Accordingly, in a first aspect, there is provided a method of passivating a crystalline silicon surface, the method comprising: cleaning the silicon surface and removing a pre-existing native oxide layer; performing a low temperature oxide growth process to form an ultra-thin silicon oxide layer on the silicon surface; and performing a low temperature depositing process to deposit a passivating dielectric layer on the ultra-thin silicon oxide layer.

In another aspect, there is provided a semiconductor structure having a passivated silicon surface, semiconductor structure comprising: a substrate including a crystalline silicon layer; a silicon oxide layer provided on at least a portion of a surface of the silicon layer, wherein the silicon oxide layer has a thickness less than approximately 15 Angstroms; and a passivating dielectric layer provided on the silicon oxide layer.

A further understanding of the functional and advantageous aspects of the disclosure can be realized by reference to the following detailed description and drawings.

### BRIEF DESCRIPTION OF THE DRAWINGS

Embodiments will now be described, by way of example only, with reference to the drawings, in which:

FIG. 1 is an illustration of an example embodiment of a passivated crystalline silicon substrate, where the passivation is provided by an ultra-thin silicon oxide layer and a passivating dielectric layer.

FIG. 2(a) provides an illustration of an example solar cell including a passivation layer including an ultra-thin silicon oxide layer and a passivating dielectric layer.

FIG. 2(b) shows an illustration of a unifacial solar cell structure employing an ultra-thin silicon oxide and an outer passivating dielectric according to a dual layer passivation scheme.

FIG. 2(c) shows an illustration of a bifacial solar cell structure employing an ultra-thin silicon oxide and an outer passivating dielectric according to a dual layer passivation scheme.

FIG. 3 provides an illustration of an example MOSFET including a passivation layer including an ultra-thin silicon oxide layer and a passivating dielectric layer.

FIG. 4 shows an illustration of thin-film, flexible, solar cell structure passivated according to an embodiment of the present disclosure.

FIG. 5 shows (a) an example implementation of silicon microelectronic circuitry/devices on thin flexible silicon, in which a silicon interface is passivated using an ultra-thin silicon oxide layer and a passivating dielectric layer, where (b) shows a detail of a single MOSFET-type structure.

FIG. 6 illustrates a multi-layer electronic device based on three silicon layers that are each passivated using an ultra-thin silicon oxide layer and a passivating dielectric layer.

FIG. 7 shows (a) the S_{eff} for an excess carried density (ECD) of 10¹⁵ cm−³ for the native oxide (aSiOₓ)-SiNₓ passivation schemes, where the oxide growth time (OGT) and the gas ratio (GR) for SiNₓ deposition were varied, and (b) the S_{eff} as a function of the inferred native oxide thickness.

FIG. 8 shows (a) the interface charge density, Q_{S}, for different GR as a function of OGT, where the Q_{S} values are inferred by fitting the ECD dependent S_{eff} values using dangling bond interface recombination model, and (b) the dangling bond defect density, NS, for different GR as a function of OGT, where the values are inferred by fitting the ECD dependent S_{eff} values using dangling bond interface recombination model.

FIG. 9 presents the spatial profile of the lifetime measured using μ-PCD tool for native oxide-SiNₓ passivation where native oxide was grown for 4 months.

FIG. 10 shows Passivation quality of crystalline silicon for chemically (HNO3) grown native oxide and PECVD SiNₓ dual layer passivation scheme.

FIG. 11 shows the passivation quality of crystalline silicon for native oxide grown in ozone rich ambient and PECVD SiNₓ dual layer passivation scheme.

FIG. 12 shows the spatial profile of the lifetime measured using μ-PCD tool for native oxide-SiNₓ passivation where native oxide was grown in ozone environment in 3 hours.

FIG. 13 presents the dark and AM1.5 IV curve of a back amorphous-crystalline silicon heterojunction cell using native oxide and PECVD SiNₓ. A cell efficiency of 16.7% is obtained for the passivation scheme with V_{OC}of 641 mV, J_{SC} of 33.7 mA/cm² and fill-factor of 0.77 for a 1 cm² untextured cell under AM1.5 solar radiation.

FIG. 14 shows the spatial profile of the lifetime measured using μ-PCD tool for native oxide-SiNₓ passivation for an inverted pyramid front textured wafer where native oxide was grown for 2 months.

FIG. 15 presents the dark and AM1.5 IV curve of a unifacial solar cell using native oxide and PECVD SiNₓ passivation. A cell efficiency of 11.6% is obtained using the native oxide and PECVD SiNₓ passivation scheme with V_{OC} of 649 mV, J_{SC} of 30.3 mA/cm² and fill-factor of 0.60 for a 1 cm² untextured cell under AM1.5 solar radiation.

### DETAILED DESCRIPTION

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure. It should be understood that the order of the steps of the methods disclosed herein is immaterial so long as the methods remain operable. Moreover, two or more steps may be conducted simultaneously or in a different order than recited herein unless otherwise specified.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure.

As used herein, the term “on the order of”, when used in conjunction with the quantity or extent of a given parameter, refers to a quantity of the parameter ranging between approximately one and ten times the stated parameter.

As used herein, the phrase “low temperature process” refers to a process performed at temperatures substantially below those typically employed for thermal growth of silicon oxide on silicon. According to some embodiments, a “low temperature process” is performed below a temperature of approximately 700° C., while according to other embodiments, a “low temperature process” is performed below a temperature of approximately 500° C. In some non-limiting examples provided below, low temperature processing is performed by processing a passivating substrate, layer or device near or below approximately 400° C.

As used herein, the phrase “ultra-thin” refers to a layer having a thickness on an Angstrom scale.

The phrase “Angstrom scale”, as used herein, according to some embodiments, is within a range of about 0.5 to 10 Angstroms, according to other embodiments is within a range of about 0.5 to 15Angstroms, according to other embodiments is within a range of about 0.5 to 20 Angstroms, and according to yet other embodiments, is within a range of about 0.5 to 100 Angstroms.

The present disclosure provides methods of passivating a surface of a crystalline silicon layer or substrate, in which an ultra-thin layer of silicon oxide, having a thickness of an Angstrom scale, is formed on a crystalline silicon surface, followed by the deposition of a passivating dielectric layer. In some embodiments, the passivating dielectric layer is formed by hydrogen-based precursors, such that during the second deposition step, hydrogen may be incorporated into one or both of the deposited layers. Structures and devices incorporating such a dual layer passivation composition are also disclosed.

As will be described in further detail below, such a process or structure provides a dual layer passivated silicon surface suitable for a wide variety of electronic and opto-electronic applications and devices. In contrary to the usual practice of etching the native amorphous silicon oxide (aSiOₓ) layer using hydrofluoric acid prior to the deposition of a passivation layer such as SiNₓ, the presence of a well-developed aSiOₓ ultra-thin layer reduces the interface dangling bond defect density, thereby enhancing device performance in selected embodiments.

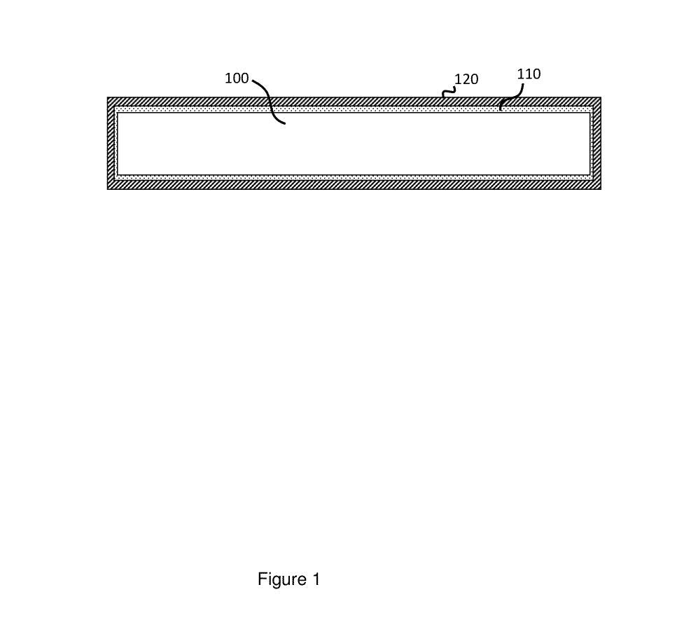

FIG. 1 illustrates an example implementation in which a planar crystalline substrate 100 (shown in cross-sectional view) is coated with an ultra-thin layer of silicon oxide 110, and where the ultra-thin layer of silicon oxide 110 is coated with a layer of SiNₓ 120. While the entire substrate is shown as being covered in the Figure, it is to be understood that in other embodiments, any or all of the surface of the silicon substrate or layer may be covered with the ultra-thin silicon oxide layer and the passivating dielectric layer.

Ultra-thin layer 110, while described herein as a “silicon oxide” layer, is composed substantially of silicon oxide, and need not possess the same stoichiometric relative concentrations of silicon and oxygen as in SiO₂. Ultra-thin silicon oxide layer 110 may also include one or more additional substances, the presence of which may contribute to passivation of the silicon surface. For example, in some embodiments, silicon oxide layer 110 includes hydrogen.

The thickness of the ultra-thin silicon oxide layer may be controlled and/or selected by pre-calibrating the deposition rate, and its dependence on one or more process parameters, such as time, temperature, and/or humidity, and/or oxygen partial pressure, and/or UV light radiant intensity, and/or any other suitable process parameter influencing the silicon oxide layer thickness.

The thickness of the passivating dielectric layer may range, in some embodiments, from 0.5 nm to 10 nm, and in other embodiments from 10 nm to 100 nm, and in other embodiments from 100 nm to a few microns. In some embodiments, the passivating dielectric layer is formed by a plasma enhanced chemical vapour deposition (PECVD) process. For example, as described in the examples below, the passivating dielectric layer may be silicon nitride (SiNₓ), which may be provided by a low-temperature PECVD process involving the hydrogen-based precursor gases NH₃ and SiH₄. Other suitable, yet non-limiting, dielectric materials include PECVD silicon nitride alloys, PECVD silicon oxynitride alloys, PECVD silicon carbide alloys, PECVD hydrogenated amorphous silicon alloys. Still other example dielectric materials for depositing the dielectric passivating layer include an oxide silicon-based layer SiOx; SiOxNy (silicon oxynitride), and an oxide non-silicon based layer (for example, hafnium oxide). It is to be understood that the dielectric layer may consist of one uniform composition or varying composition or varying sublayers. It is also to be understood that the one or more additional layers may be provided in addition to the passivating dielectric layer. In one example embodiment, the passivating dielectric layer may be formed via a process (for example, PECVD) performed at a temperature ranging from approximately ambient temperature to 400 degrees C. In another example embodiment, the passivating dielectric layer may be formed via a process (for example, PECVD) performed at a temperature ranging from approximately 400 degrees C. to 800 degrees C. In another example embodiment, the passivating dielectric layer may be formed via a process (for example, PECVD) performed at a temperature greater than approximately 800 degrees C.

The silicon surface may be prepared prior to the formation of the ultra-thin silicon oxide layer, where the preparation may include the removal of a pre-existing native oxide layer. Suitable preparation steps include RCA cleaning, dilute HF dip, deionized water rinse, and spin drying. Silicon surfaces can include well-oriented surfaces such as (100) and (111), regular pyramidal surfaces with (111) facets, regular patterned or textured surfaces, random pyramidal surfaces, and random patterned or textured surfaces, as further described below. Furthermore, the silicon surface may be formed from single crystal silicon or polycrystalline (multicrystalline) silicon.

According to some embodiments, the methods disclosed herein provide surface passivation of crystalline silicon wafers through the controlled deposition of an ultra-thin layer of native silicon oxide, which is grown at or near ambient temperature, optionally with controlled humidity, onto which a layer of passivating dielectric is deposited via a low-temperature process, such as the deposition of SiNₓ by PECVD. In some embodiments, the native oxide layer may be formed over a time duration greater than 50K minutes, while according to other embodiments, the time duration may exceed 100K minutes, and according to other embodiments, the time duration may exceed 150K minutes. The humidity may be adjusted to obtain a given rate of silicon oxide growth. In one example, the humidity is maintained near approximately 50%.The process parameters of the PECVD deposition may be varied in order to obtain a SiNₓ layer of suitable thickness and composition. For example, in the examples provided below, a SiNₓ layer is obtained using operating conditions at the low plasma power of 25 W and chamber pressure of 1 Torr. It is to be understood that these parameters are merely provided for illustrative purposes, and that other process parameters may alternatively be selected in order to obtain a SiNₓ layer (or layer of another suitable passivating dielectric) with a desired thickness.

In other embodiments, the layer of silicon oxide is thermally grown in a low-temperature thermal environment prior to the deposition of the passivating dielectric layer. As in the case of a native oxide layer, the humidity may be selected to obtain a given rate of silicon oxide growth. In one example, the humidity is maintained near approximately 50%.

Although the examples provided below illustrate the formation of ultra-thin silicon oxide layers by native oxide growth in ambient conditions, it is to be understood that the ultra-thin silicon oxide layer may be provided according to a wide range of low-temperature deposition methods, provided that the deposited layer has a thickness on an Angstrom scale.

For example, in an alternative embodiment, the intermediate ultra-thin silicon oxide layer may be formed according to other processes such as, but not-limited to, silicon oxide grown in ozone and other oxidizing chemicals (such as, for example, a solution of H₂SO₄ and H₂O₂, a solution of HNO₃, or a solution of H₂O₂). Passivation using an ultra-thin silicon oxide layer grown using ozone and PECVD SiNₓ may be performed to provide comparable passivation quality. This alternative method is illustrated in the examples below, where it is shown that an SRV of approximately 15 cm/sec was obtained using ozone for silicon oxide growth. Alternatives to these would include growth in an environment where there is catalytic dissociation of oxygen, hot-wire dissociation of oxygen, and provision for oxygen ions and neutrals using other processes. Other oxidation agents, such as HNO₃ acid, and a sulfuric acid and hydrogen per-oxide mixture may alternatively be employed to oxidize the surface. Yet another oxidation environment would be liquid water solutions, pure or with appropriate electrolytes or admixture of ozone, at ambient or boiling temperatures or temperatures there between.

In one example implementation, described in further detail in the examples below, PECVD SiNₓ is deposited at approximately 400° C. on the native aSiOₓ and grown for various time periods. In one example, the growth of the native oxide layer is performed over four months. Using surface recombination velocity (SRV) as the parameter to characterize the interfacial passivation quality, an SRV of less than 8 cm/s at excess carrier density (ECD) of 10¹⁵ cm⁻³ (7 cm/s at ECD 5×10¹⁴ cm⁻³) is achieved for the passivation scheme. The passivation quality in terms of SRV is similar to the lowest reported values for other passivation schemes. Using the dangling bond interface recombination model [26, 27] and ECD-dependent lifetime measurements, it is shown that the inferred interface defect density N_{S} is as low as 7.2×10⁹ cm⁻² and inferred interface surface charge density Q_{S} is 4.3×10¹¹ cm⁻².

The low-temperature passivation methods, as disclosed in selected embodiments herein, are compatible with a wide range of semiconductor device manufacturing protocols. For example, selected methods disclosed herein are compatible with manufacturing of semiconductor devices, including, but not limited to, metal oxide semiconductor field effect transistor (MOSFET), flash memory (E²PROM), photovoltaic (PV) solar cell and allied microelectronic devices. In particular, MOSFET and flash memory devices are two common electronic semiconductor device types for which the role of a low-temperature grown oxide based dielectric that effectively passivates the cSi surface can be crucial.

In one example embodiment, local layers of doped semiconductor materials may be formed on the dual passivating layer in order to form one or more semiconductor devices. For example, a layer of a first doped material may be deposited over a first region of the passivating dielectric layer, and a layer of a second doped material may be deposited over a second region of the passivating dielectric layer, and a suitable firing process may be performed in order to form a p-type hetero-/homo-junction with the crystalline silicon surface over the first region and an n-type hetero-/homo-junction with the crystalline silicon surface over the second region. One or more of the first doped material and the second doped material may be formed according to a simple printing process, such as ink jet printing or silk screen printing. Example processing conditions for the firing step include thermal processing at a temperature of approximately 750° C. for a time duration of approximately 60 s-120 s. Suitable electrical contacts may then be formed on or augmented on the first region and the second region. The first region and the second region may be suitably spaced to form a semiconductor device, such as a photovoltaic cell, a MOSFET device, a flash memory device, or other semiconductor devices.

In some example embodiments, the passivation methods disclosed herein may be employed to passivate the surface of a wide variety of crystalline silicon-based solar cells, including standard front contact solar cell, back contact solar cells, selective and/or passivated emitter front contact solar cells. Furthermore, the low-temperature synthesized ultra-thin oxide-silicon nitride passivation embodiments provided herein can be employed to fabricate ultra-thin silicon PV cells based on the MIS (metal-insulator-semiconductor) cell configuration.

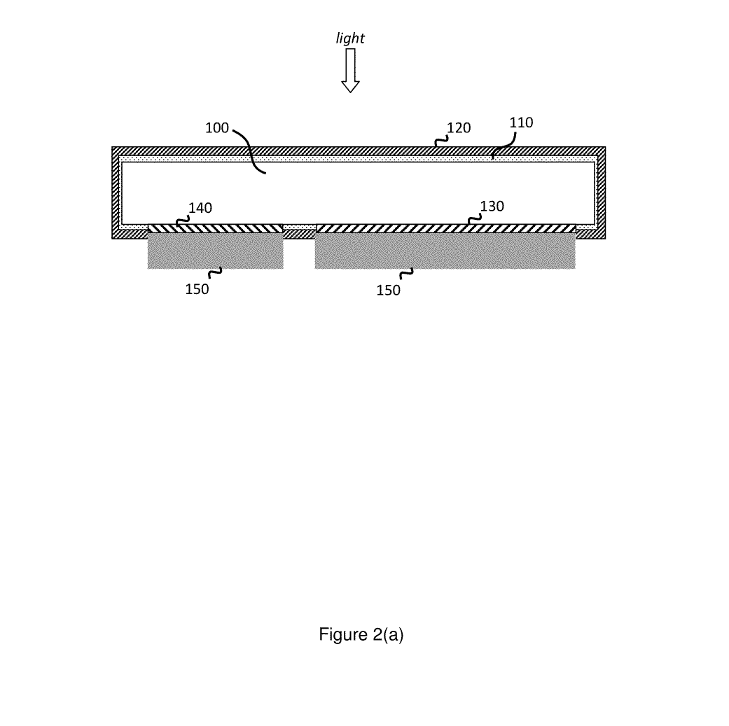

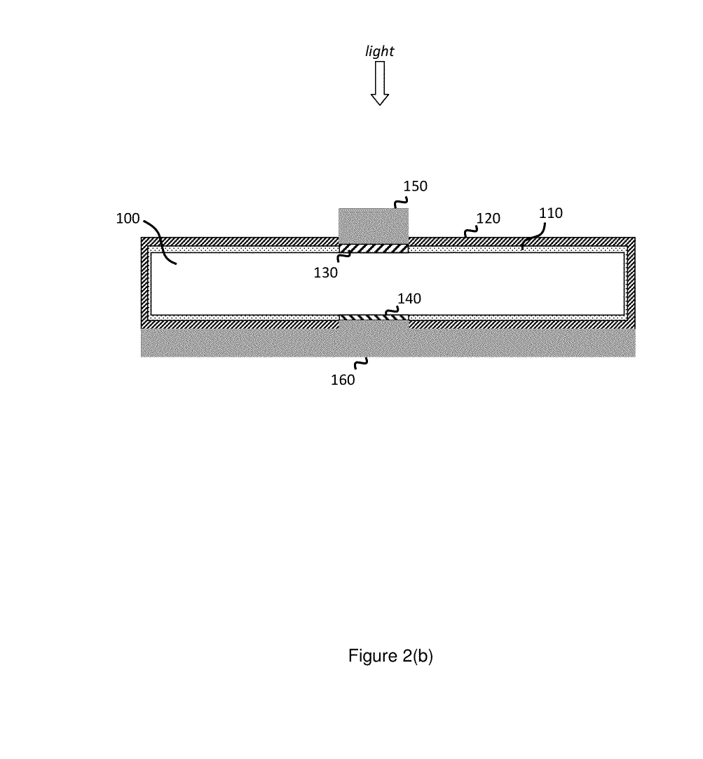

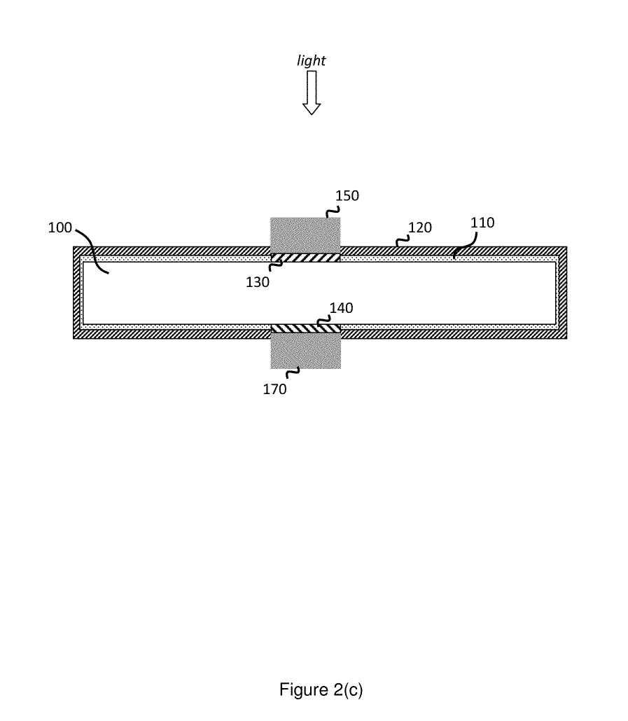

Referring now to FIG. 2(a), an example implementation of a solar cell is shown, in which a silicon interface is passivated according to an embodiment of the present disclosure. A crystalline silicon wafer 100, in this case, double-side polished, is passivated by ultra-thin silicon oxide layer 110, on which is deposited silicon nitride 120.

On the front, direct light-facing side of the wafer, the dual layer passivation scheme provides for both chemical passivation through dangling bond termination and field passivation through the presence of charge in the layer(s), as well as providing a front surface field which serves as a minority carrier mirror. Further, the angstrom thin oxide layer is of negligible thickness to affect optical impedance matching; in this case, the progression of the change in index while progressing from silicon to air is from high to low, consistent with providing for antireflection.

On the rear side of the wafer, an interdigitated pattern of pN and nN junctions and contacts are formed by appropriately opening windows through the dual passivation layer. Specifically, pN junctions 130 are formed by the deposition of p-type hydrogenated amorphous silicon directly onto N-type crystalline silicon and nN junctions 140 are formed by the deposition of n-type hydrogenated amorphous silicon directly onto N-type crystalline silicon. Electrodes 150 are formed by depositing metal contacts directly onto the pN and nN junctions. As noted above, the preceding embodiments, as applied to a silicon solar cell, provide a suitable composition for exhibiting anti-reflection properties. This can be appreciated by comparing an example embodiment of the present disclosure, involving an ultra-thin silicon oxide layer sandwiched between a silicon substrate and a SiNₓ layer, to known structures in which a thicker silicon oxide layer, having thickness of several nanometers to tens of nanometers or more, is sandwiched between a silicon substrate and a SiNₓ layer. In the former case, corresponding to an embodiment of the present disclosure, the ultra-thin silicon oxide layer reduces the effective dielectric constant at the interface, thereby enhancing the gradient index effect provided by the transition from the thicker SiNₓ layer to the silicon substrate.

As described further in the examples below, a cell efficiency of 16.7% was obtained for native oxide/SiNₓ passivated cells with V_{OC} of 641 mV, J_{SC} of 33.7 mA/cm² and fill-factor of 0.77 for a 1 cm² untextured cell (all measurements having been performed under AM 1.5 global spectrum illumination).

Although the preceding embodiments disclose methods and structures in which the ultra-thin silicon oxide layer and the passivating dielectric layer are applied to planar crystalline substrates, it is to be understood that the present disclosure is not intended to be limited to planar substrates, and that the dual passivation layers may be applied to a wide variety of surface geometries.

For example, a common design feature of solar cell substrates is a textured surface, where the texturing is configured to enhance light trapping. An example of such a light trapping surface texturing is the formation of random pyramids, or inverted pyramid structures, which can be formed in silicon structures by appropriate alkaline etching techniques, or appropriate mask-writing and alkaline etching techniques, respectively. Accordingly, in one example implementation, the preceding embodiments may be adapted to be provided on such a textured surface by following appropriate surface preparation steps similar to that of a plane wafer described above.

In other embodiments, the dual layer passivation layer scheme described above may be employed to form a cell device using an amorphous silicon-crystalline silicon heterojunction. According to the present example embodiment, and as further described below, openings may be formed in the dual passivation layer on the front and back surfaces of the substrate. Doped amorphous silicon layers may be formed within the openings, and metal contacts (e.g. metal fingers) may be formed on the doped amorphous silicon layers. Accordingly, devices formed according to such an embodiment include a laterally and inherently thin layer of doped amorphous silicon, and may be referred to as “laterally inherently thin” (LIT) cells.

FIG. 2(c) illustrates an example embodiment of such a structure in a unifacial configuration. A crystalline silicon wafer 100, the surfaces of which can be appropriately patterned/textured, is passivated by ultra-thin silicon oxide layer 110, on which is deposited silicon nitride 120, forming the dual passivation layer described above.

On both sides of the wafer, closely spaced windows with small areas and are appropriately opened through the dual passivation layer. In some embodiments, the spacing of the windows may range from approximately a few microns or less, tens of microns or less, or hundreds of microns or less, where the spacing may be determined by the transport properties of the device. For example, the windows may be formed with an 80 um spacing, and a line-width 4 um. In one example implementation, the total fractional area of the openings may be approximately a few percent or less (e.g. approximately 3-7%) so as to minimize shadowing losses. The windows can be employed, for example, to form narrow gridlines and busbar patterns. In the example embodiment shown in the figure, pN junctions 130 and nN junctions 140 are formed by appropriately depositing p-type and n-type hydrogenated amorphous silicon directly onto N-type crystalline silicon, respectively. An appropriate thin intrinsic hydrogenated amorphous silicon layer can optionally be included between the doped amorphous layer and crystalline silicon, for example, with a thickness of approximately 1-10 nm. Metal contact 150 is selectively deposited onto pN junction 130 on the front of the device, and a metal contact 160 is provided on the back surface of the device, thus forming a unifacial solar cell device.

The preceding example embodiment may be beneficial in maintaining high quality surface passivation for regions with no doped layers, while avoiding light induced degradation of the doped amorphous silicon layers. Moreover, there is little or no parasitic optical absorption loss over the AM1.5 solar spectrum for the example device shown in FIG. 2(b) compared to typical heterojunction cells that have parasitic optical absorption loss due to the presence of doped layers, and also due to the often present indium tin oxide layer, in the light exposed regions. Indeed, through the use of silicon oxide and silicon nitride which are substantially larger bandgap materials than hydrogenated amorphous silicon and indium tin oxide, typically used in amorphous-crystalline silicon heterojunction cells, the reduction in optical absorption loss is significant (with little or essentially no optical absorption over the AM1.5 solar spectrum).

In FIG. 2(c) a bifacial cell structure is shown. A crystalline silicon wafer 100, the surfaces of which can be appropriately patterned/textured, is passivated by ultra-thin silicon oxide layer 110, on which is deposited silicon nitride 120. pN junctions 130 and nN junctions 140 are formed in a manner similar to unifacial embodiment shown in FIG. 2(b). However, back metal contact 170, in the present bifacial structure, is selectively deposited in order to allow light to enter the cell through the back surface in addition to the top surface.

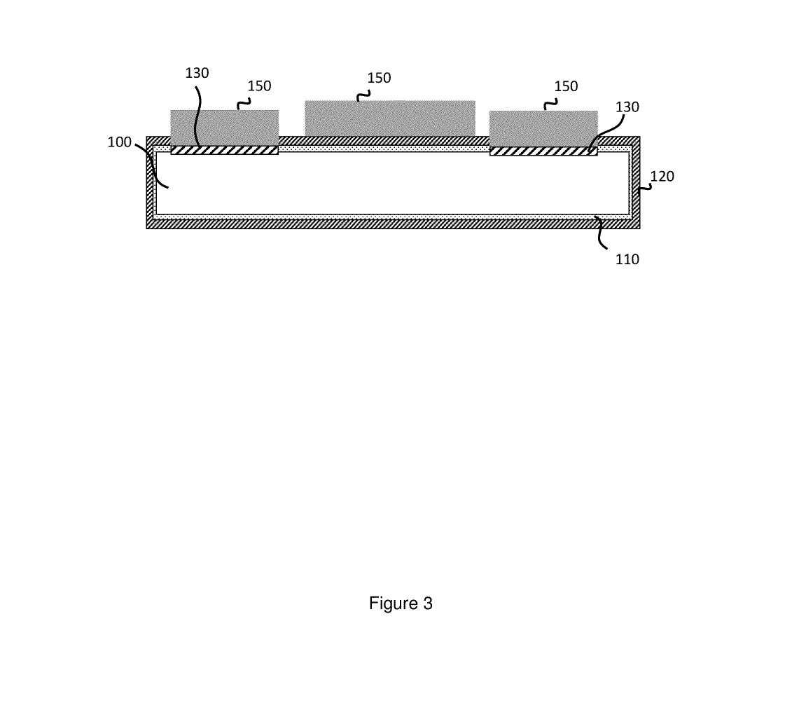

Referring now to FIG. 3, an example implementation of a MOSFET-type structure is shown, in which a silicon interface is passivated according to an embodiment of the present disclosure. Specifically, the figure shows the cross-sectional view of a p-channel enhancement mode MOSFET-type structure that can be fabricated using the present ultra-thin oxide and SiNₓ passivation methods (or using a passivating dielectric material other than SiNₓ). For example, according to one embodiment, the planar crystalline silicon substrate 100 is coated with ultra-thin silicon oxide layer 110 and SiNₓ layer 120. The p-doped hydrogenated amorphous silicon layer regions 130 function as the drain and source of the device.

As shown in the Figure, the p-doped regions 130 may be vertically depressed to an appropriate depth in the silicon wafer so as to improve the contact between the p-channel, which is immediately below the oxide layer, and the drain and source. Vertical depression into the silicon wafer can be attained by appropriate etching of silicon; for example, by alkaline etching using KOH. Suitable metal contacts 150 are deposited on top of the doped amorphous silicon regions forming the electrode contacts. Metal contact 150 deposited on the dielectric layer between the drain and the source serves as the gate electrode of the device. Examples of metals for forming metal contacts 150 include one or more of aluminum, nickel, chromium, silver, palladium, platinum, copper, alloys thereof, and layers thereof where specific functionalities are required such as an adhesive/bonding layer or a barrier layer.

In the preceding embodiments, the devices are synthesized using doped variations of hydrogenated amorphous silicon. These devices can also be fabricated using alternative materials, alloys, and combinations thereof. Example alternatives include n-doped and p-doped microcrystalline silicon, hydrogenated amorphous silicon alloys, metals, metal alloys, and other doped dielectric alloys.

In the preceding embodiments, the passivating dielectric layer can further extend to include doped dielectrics where the dopant material would alter its properties. For example, silicon nitride could be doped with an appropriate metallic dopant. In yet another example, the passivating dielectric layer may be a semiconductor such as amorphous silicon or hydrogenated amorphous silicon, which can act as dielectrics. Such semiconductors may also be doped.

The preceding embodiments may also be adapted to provide silicon-based flash memory devices, in which one or more silicon surfaces are passivated according to the dual layer passivation embodiments disclosed herein. It is to be understood that the thickness of the passivating dielectric layer (e.g. PECVD SiNx) may be adjusted according to the requirements of a given device or design.

This passivation scheme disclosed above may be employed for the passivation of devices fabricated in/on thin and flexible semiconductor films, where a dielectric layer providing high quality interfacial passivation grown at low temperatures is needed for such thin silicon wafers. For example, in the context of silicon wafer production, significant progress has recently been made to produce thin silicon wafers with thicknesses of 50 microns, 20 microns, 5 microns, and lower, using kerf-free wafering techniques.

Accordingly, in some embodiments, silicon surfaces of flexible, high-density and low-cost silicon-based devices may be passivated according to methods disclosed herein. In particular, selected embodiments disclosed herein may enable the fabrication of low-cost solar cells due to reduced material costs, at low thermal budget, and/or high photovoltaic conversion efficiency. The integration of high-quality interfacial passivation prepared at low-temperature may be employed to provide efficient light-weight flexible ultra-thin silicon photovoltaic solar cells.

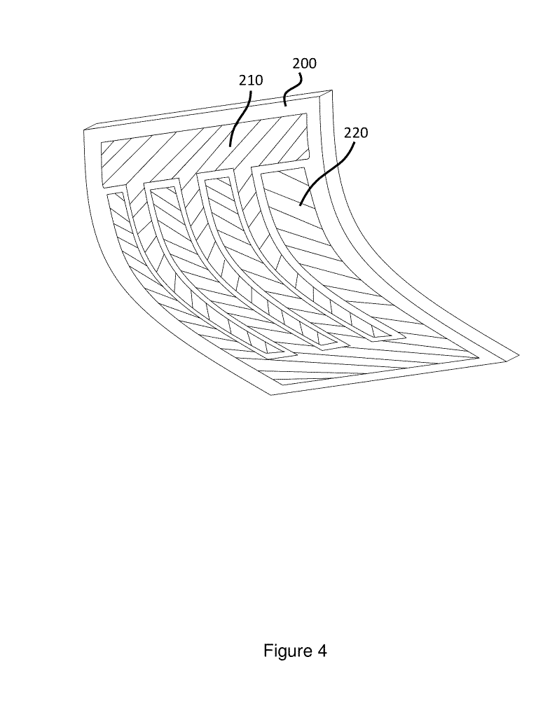

Referring now to FIG. 4, an example implementation of a silicon photovoltaic solar cell on thin flexible silicon is shown, in which a silicon surface is passivated according to aforementioned embodiments of the present disclosure. Ultra-thin silicon oxide and SiNx dual passivation layers are deposited on flexible thin silicon substrate 200. Silicon substrate 200 is also contacted with interdigitated n-doped hydrogenated amorphous silicon and metal contact electrode, collectively denoted 210, and p-doped hydrogenated amorphous silicon and metal contact electrode, collectively denoted 220.

The integration of high-quality interfacial passivation prepared at low-temperature may also be employed in the fabrication of micron- and sub-micron scaled MOS-type and associated devices. Such methods may be compatible with existing synthesis equipment, and may provide low-cost high-density light-weight, flexible, and/or thin silicon microelectronic circuitry/devices.

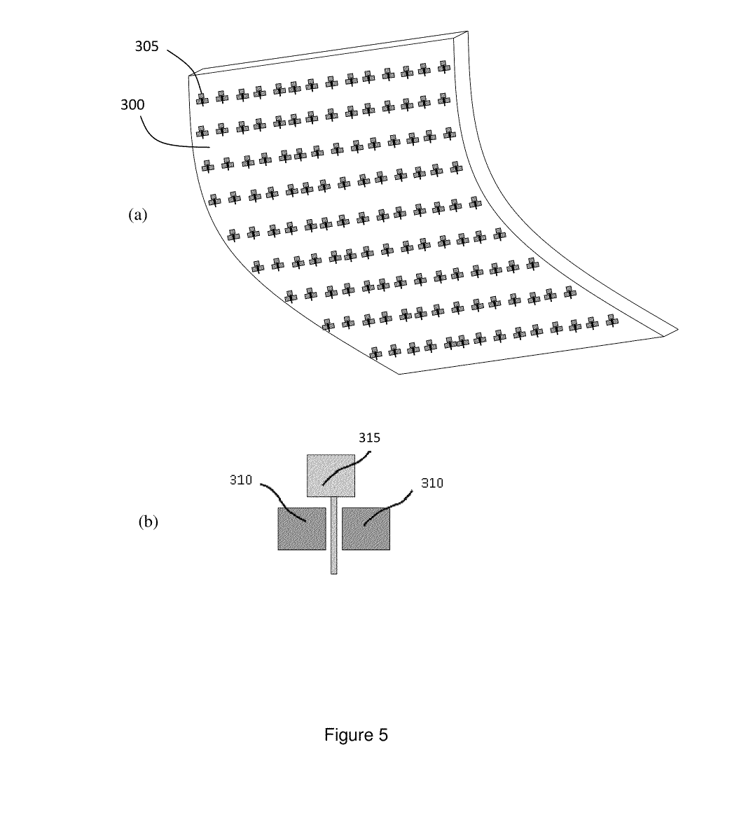

Referring now to FIG. 5(a), an example implementation of silicon microelectronic circuitry/devices on thin flexible silicon is shown, in which a silicon interface is passivated according to an embodiment of the present disclosure. An ultra-thin silicon oxide layer and SiNₓ passivation layer are deposited on flexible thin silicon substrate 300, is shown with a high density of MOSFET-type structures 305. As shown in FIG. 5(b), each MOSFET-type structure 305 includes p-doped hydrogenated amorphous silicon contacts 310, which contact silicon substrate 300 and function as the drain and source, and the gate metal electrode 315 deposited on the ultra-thin silicon oxide and silicon nitride on the flexible silicon. It is to be understood that the silicon nitride layer can be appropriately thinned or/and substituted, and an appropriate alternative over layer providing high dielectric properties, for example such as hafnium oxide, can be used to effect desired device performance.

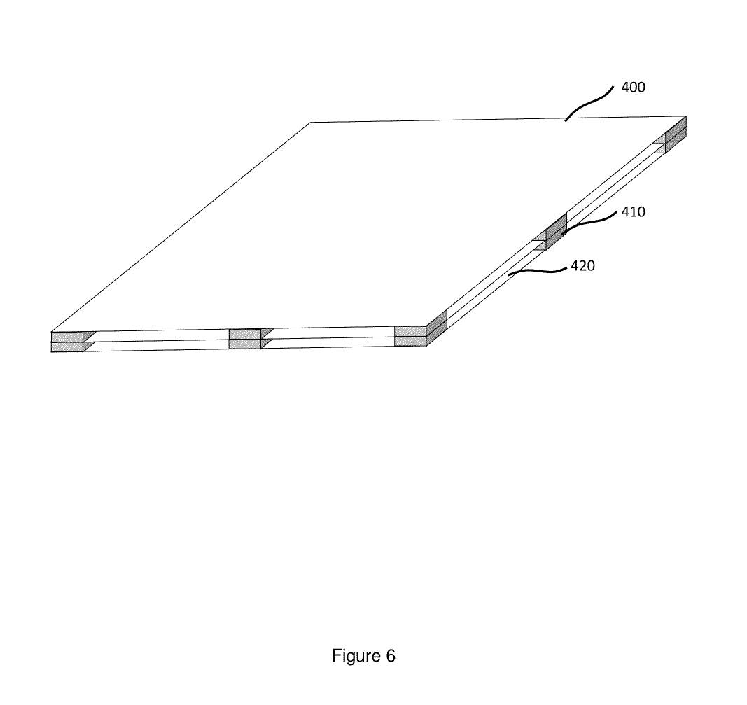

FIG. 6 illustrates an example implementation of a multi-layer microelectronic structure formed from a plurality of thin flexible silicon sheets (or foils) that are arranged in a spaced relationship, and where a silicon interface of each sheet is passivated according to an embodiment described above. Each silicon sheet or silicon foil 400 includes a high density of microelectronic structures (e.g. microelectronic circuits or devices such as MOSFET-type structures). Adjacent sheets are separated by spacers 410, thereby providing a gap 420.

Gap 420 may be employed for cooling purposes (e.g. active and/or passive cooling). For example, forced air cooling may be employed to provide active cooling of the heat generating microelectronic circuitry/devices residing on the sheets. Gap 420 can equivalently be filled with a suitable thermally conductive material, in solid or liquid form. Non-limiting examples of suitable thermally conductive materials include copper foils, deposited copper films, conducting gels, liquids, and other thermally conductive media. The thermally conductive material provided within gap 420 may be in thermal communication with an external heat sink.

Accordingly, selected embodiments provided herein may be employed to provide high-density electronic, computing and/or optoelectronic devices with high spatial density in three dimensions and suitable passivation of silicon surfaces.

The following examples are presented to enable those skilled in the art to understand and to practice embodiments of the present disclosure. They should not be considered as a limitation on the scope of the present embodiments, but merely as being illustrative and representative thereof.

### EXAMPLES

Double-side polished n-type (100) FZ wafers with resistivity of 1 to 5Ω-cm were used in this passivation study. The wafers were cleaned using standard RCA cleaning steps [28]. The wafers were subsequently dipped in 5% HF for 2 minutes to etch the native oxide and then kept in a clean-room environment, with ambient average humidity of 50% and temperature of 25° C., for different durations; during this period the wafers were stored within a typical 25 wafer carrier box.

The duration for the growth of native oxide layers prior to the deposition of SiNₓ was varied from 20 min to 40,000 min. The 100 mm circular wafers were cut into four quadrants prior to the deposition of SiNₓ deposition.

Silicon nitride deposition was carried out using the Oxford PlasmaLab 100 direct rf PECVD system. During a series of preliminary experiments it was determined that higher SiNₓ deposition temperatures resulted in better passivation, and accordingly all the SiNₓ depositions were carried out at 400° C. While the use of low chamber pressure (200 mTorr) and high plasma power (100 W) have been reported for SiNₓ passivation studies using a similar system [15], it was found that such process parameters resulted in significant non-uniformity in film quality.

Instead it was found that operating at a higher chamber pressure of 1 Torr and lower plasma power of 25 W yielded uniform and reproducible films. Further, the use of higher chamber pressure allowed better convective heat transfer from the substrate holder to the wafer and hence required a lower preheating period compared to that at a lower chamber pressure. Operating at higher plasma power increased the deposition rate of SiNₓ albeit with no significant change in the passivation quality. Accordingly, all SiNₓ depositions were carried out at the low plasma power of 25 W and chamber pressure of 1 Torr.

Precursor gases for silicon nitride depositions consisted of NH3, which was held constant at a flow rate of 50 sccm, and 5% silane in nitrogen at flow rates ranging from 200 sccm to 550 sccm. The precursor gas ratio (GR), as used herein, is defined as the quotient of (SiH₄+N₂) to NH₃ flow rates.

The effect of varying the GR from 4 to 7 was explored for samples where the native oxide growth time (OGT) ranged from 20 min to 2K min. A small enhancement in passivation was observed for these relatively short OGTs. On the other hand, excellent passivation enhancement in quality was observed for native oxide growth times of the order of 40K min. For these samples, the GR was varied from 4 to 11. For all samples the SiNₓ deposition time was held constant at 7 min; further, SiNₓ was deposited on both sides of the wafer to yield a symmetric set of passivation layers. Thicknesses and refractive indices of the SiNₓ films were measured using SOPRA GES 5E spectroscopic ellipsometer.

The excess carrier density (ECD) dependent effective minority carrier lifetime, τ_{eff}, was measured using a Sinton Silicon Lifetime Tester WCT-120 system. Transient and Quasi-Steady-State Photo-Conductance (QSSPC) methods were used to measure injection-dependent τ_{eff} of the sample [29]. Spatial distributions of the lifetime for different samples were measured using Semilab's WT-2000 PVN Microwave Photo Conductance Decay (p-PCD) instrument.

In fitting the data obtained from SE measurements, we included an ultra-thin native oxide layer between the cSi substrate and SiNₓ layer. Silicon nitride layer thickness of ˜93 nm thickness was inferred from the SE measurements which corresponds to a growth rate of 13.3 nm/min. Refractive index (at 633 nm wavelength) increased from 1.9 to 2.06 with increasing silane precursor concentration, i.e., the GR. The increase in the refractive index is consistent with a transition from a sub-stoichiometric to a silicon-rich silicon nitride film [15].

τ_{eff} values at an excess carrier density of 10¹⁵ cm⁻³ (unless stated otherwise) were used to calculate the effective surface recombination velocity (SRV), S_{eff},

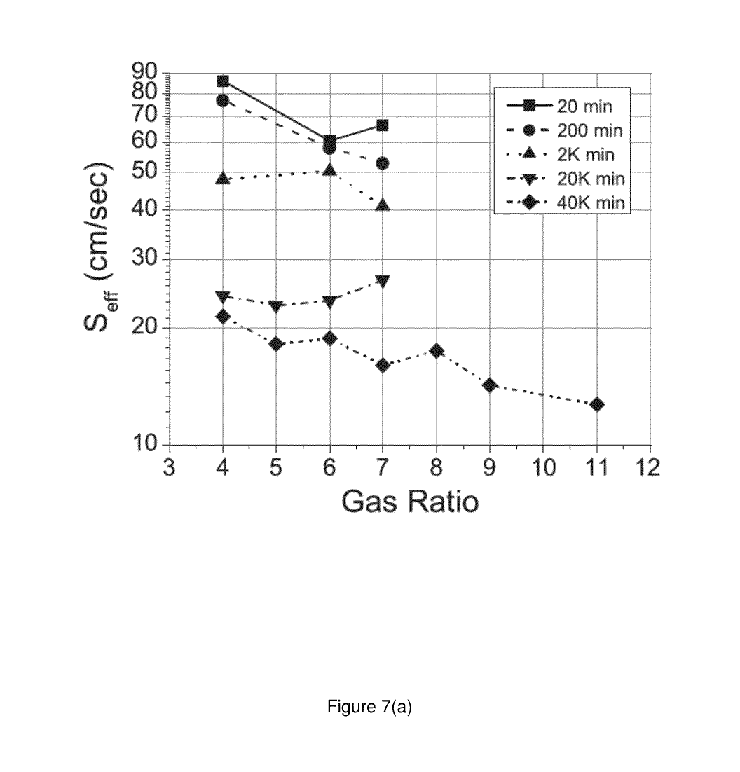

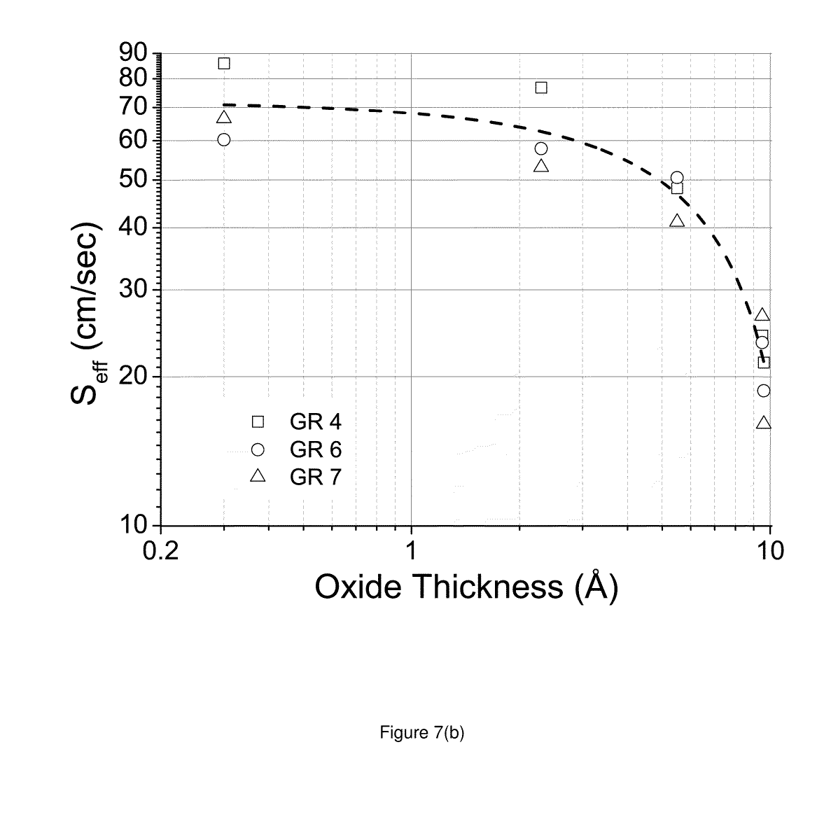

S_{eff}=W/(2τ_{eff}) (1)

where W is the thickness of the sample and the bulk lifetime is assumed to be infinite. FIG. 7(a) shows the effective SRV values at an ECD of 10¹⁵ cm⁻³ for samples with a range of native OGTs as a function of the GR. It is evident from the figure that the passivation quality for the aSiOx-SiN layers generally improves with the native oxide growth time and increasing GR. In particular, we find that a reduction in SRV with OGT is moderate up to OGT of 2K min, however significant improvement in passivation is observed for OGT of 20K min and yet a further enhancement for OGT of 40K min. For the sample with an OGT of 40K min, the SRV is reduced further with an additional increase in the GR from 7 to 11.

FIG. 7(b) shows the passivation quality as a function of native oxide thickness. Native oxide thicknesses are measure using Angled Resolved x-ray photoelectron spectroscopy. Thickness values are of same of order of magnitudes in comparison to the thickness measured in Morita et al.'s investigation of native oxide growth [30] on n-type cSi wafer with doping concentration similar to that used in this study. As seen from the figure increase in the native oxide thickness corresponds to an improvement in the passivation quality. The limiting oxide thickness reflected in FIG. 7(b) reflects the saturation value of 8 Å with native oxide growth time as reported by Morita et al. [31].

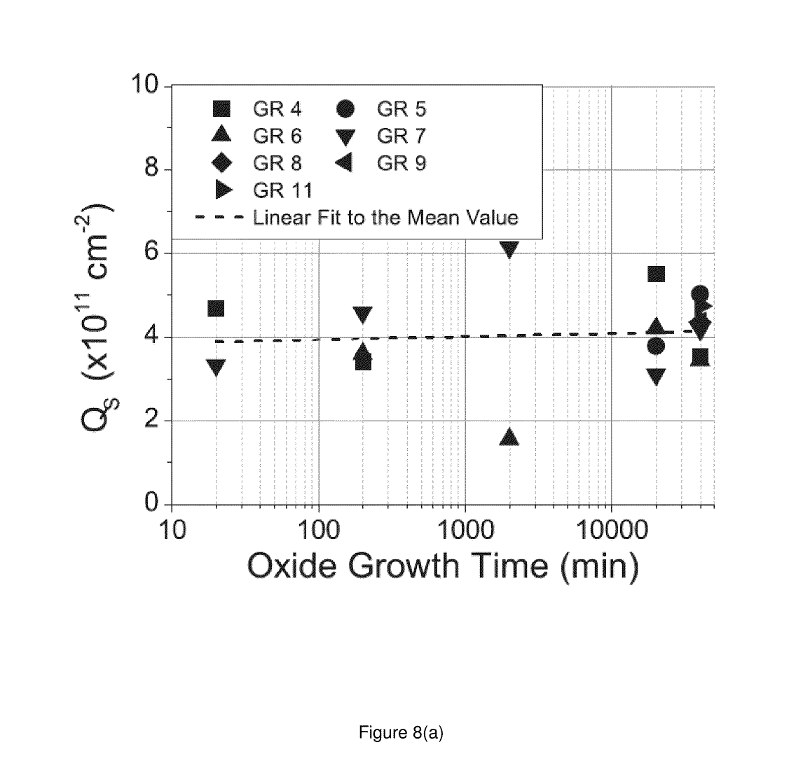

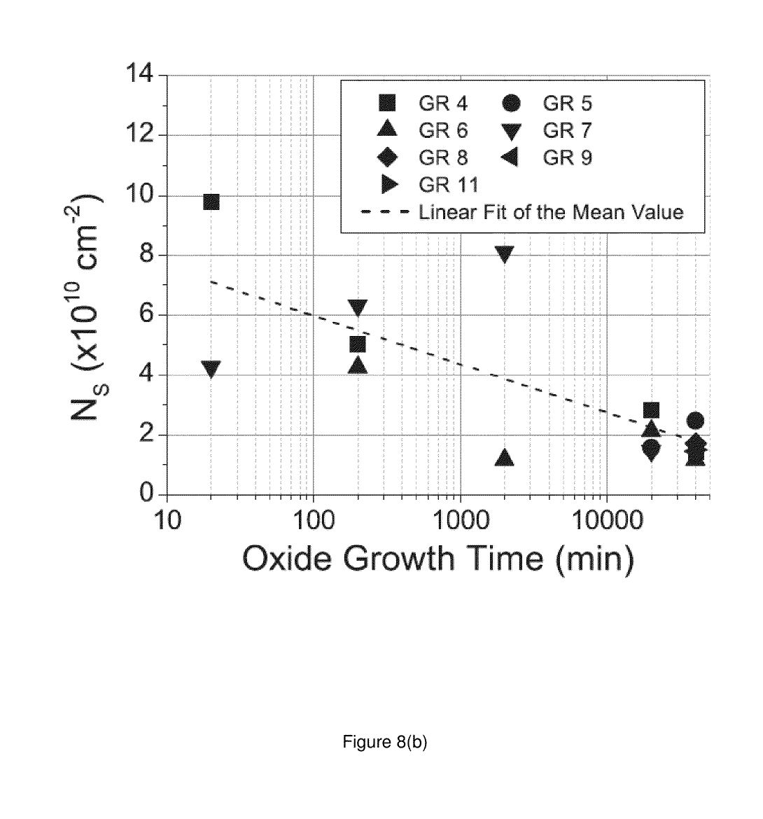

The surface charge density, Q_{S}, and defect density, N_{S}, are inferred from the ECD dependent S_{eff} and simple closed form (SCF) dangling bond interface recombination model [26, 27]. The extracted Q_{S} and N_{S} values are shown in FIG. 8(a) and FIG. 8(b), respectively. Notwithstanding some scatter in the data, the average trapped charge density remains essentially unchanged over the range of OGT studied here as well as the GR. However, on average the interfacial dangling bond defect density decreases with increasing OGT, which corresponds to the observed reduction in SRV. These results indicate the important role of a native oxide layer of less than 1 nm in thickness, along with hydrogenated silicon nitride, in markedly reducing the defect density at the interface.

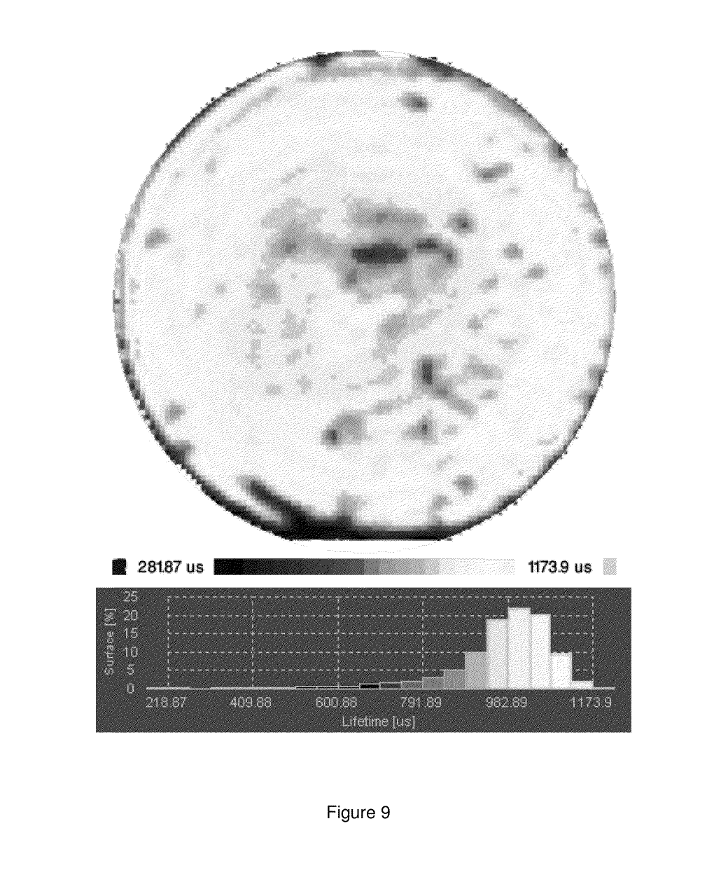

A sample with a native oxide growth time of 160K min was also prepared using identical SiNₓ deposition conditions stated above and at a GR of 7. FIG. 9 shows the spatial profile of the passivation quality measured using the μ-PCD tool. A corresponding lifetime of 1.7 ms was measured which is equivalent to S_{eff} of ˜8 cm/s.

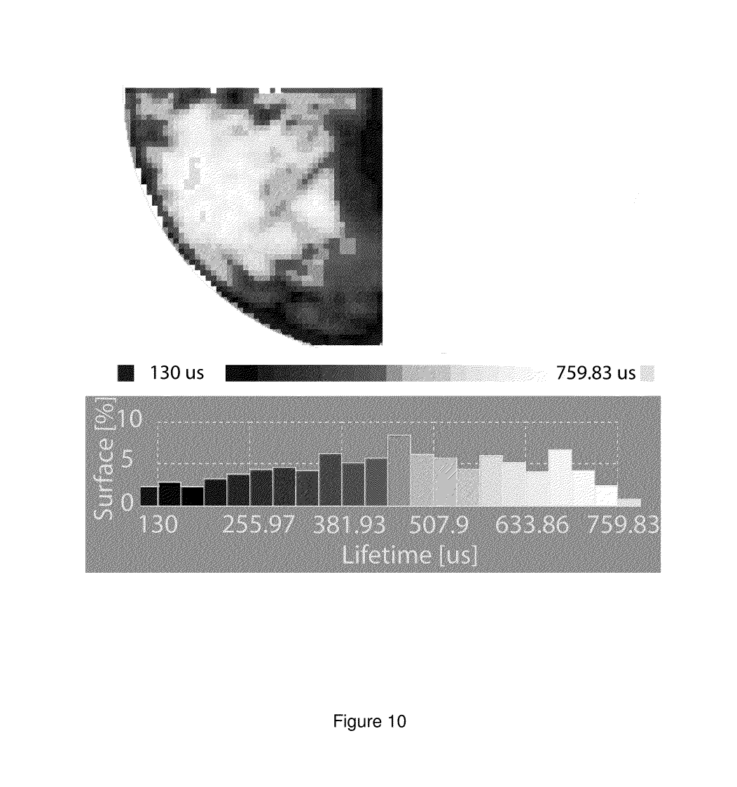

Given the observed importance of the native amorphous oxide layer, we also explored the potential of chemically grown oxide playing an equivalent role. Using a 62% nitric acid solution at 60° C., amorphous silicon oxide was grown on a quadrant of a cSi wafer by submerging it in the bath for 60 min. The spatial distribution of the passivation attained, for a process that has yet to be optimized, is shown in FIG. 10. This result corresponds to a lifetime of 0.76 ms or an SRV of 18 cm/sec as measured using the Sinton lifetime tester. Further optimization of the chemically grown oxide and PECVD SiNₓ passivation is expected to yield results similar to the native grown oxide layers.

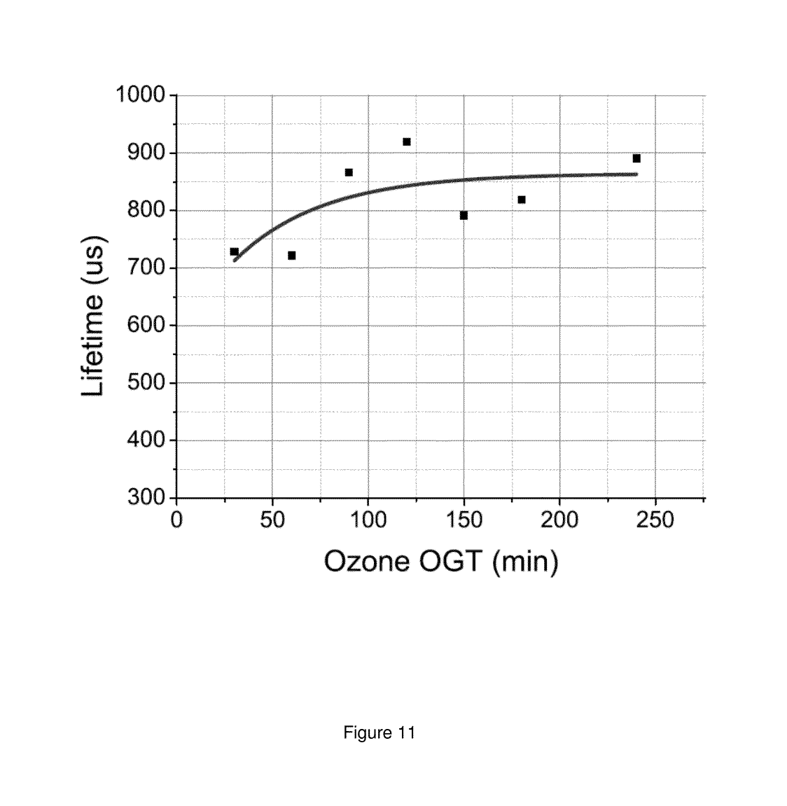

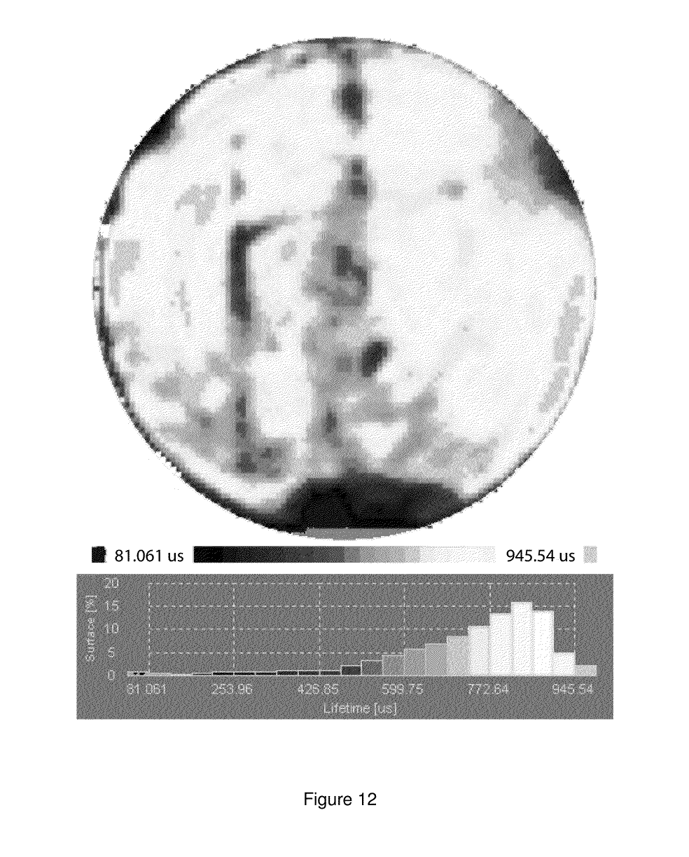

Ozone can also oxidize the silicon at low temperature. Passivation qualities of ultra-thin oxide layers grown in ozone rich environment for different times and PECVD SiNₓ deposited using the above optimized condition are also studied. Atmospheric oxygen is used for ozone generation using a UV light source. FIG. 11 shows the passivation quality measured using Sinton lifetime tester for different oxide growth time in ozone rich environment. FIG. 12 also shows the spatial variation of passivation quality measured using the μ-PCD tool. A lifetime of ˜0.9 ms was achieved for the passivation scheme that corresponds to an SRV of 15 cm/sec.

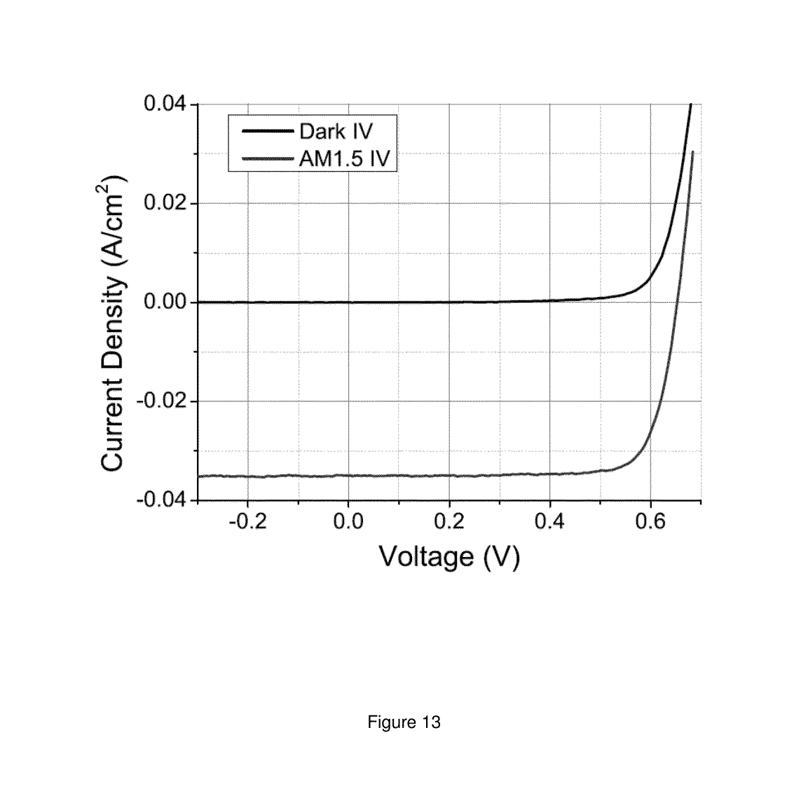

The passivation scheme is utilized to fabricate back amorphous-crystalline silicon heterojunction [32] PV solar cell. Double side polished n-type FZ wafers with 1-5Ω-cm resistivity were used for the cell fabrication. Doped amorphous silicon layers are deposited at 170° C. using DC saddle field electrode configuration to create the emitter and collector layers. Around 75 nm thick SiNₓ layers are deposited on the front light-facing side to provide anti-reflective properties. Interdigitated chromium-silver metal layers are deposited on the back-side using e-beam thermal evaporation process. The dark and AM1.5 light IV curves of the back amorphous-crystalline silicon heterojunction cell using native oxide and PECVD SiNₓ are shown in FIG. 13. As observed from the AM1.5 light IV curve a cell efficiency of 16.7% is obtained for the passivation scheme with voc of 641 mV, JSC of 33.7 mA/cm² and fill-factor of 0.77 for a 1 cm² untextured cell under AM1.5 solar radiation. The high short-circuit current is a testament to the optically non-absorbing property of the facile native oxide-silicon nitride passivation layer.

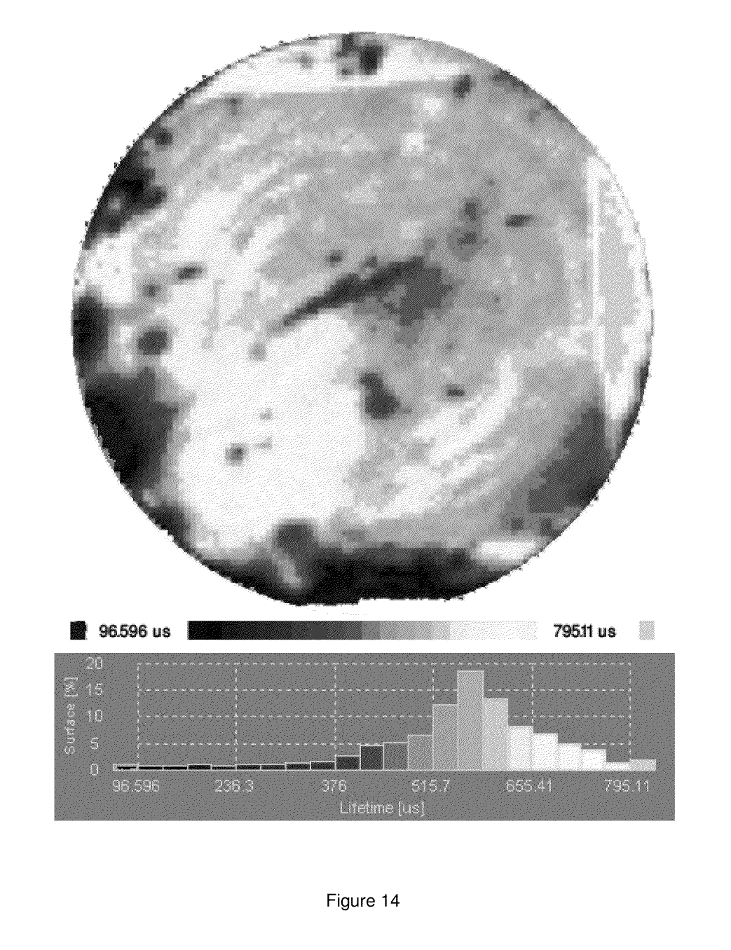

The passivating scheme is also implemented on wafers with inverted pyramid textured front surface. FIG. 14 shows the spatial profile of the passivation quality measured using the μ-PCD tool. A corresponding lifetime of 0.75 ms was measured which is equivalent to S_{eff} of ˜18 cm/s. Effective surface area increases with the texturing of a surface. However, the preceding SRV is calculated using the measured effective lifetime and assuming that both sides of the wafer are polished. Accounting for the actual area would result in an actual SRV which is better than that stated above.

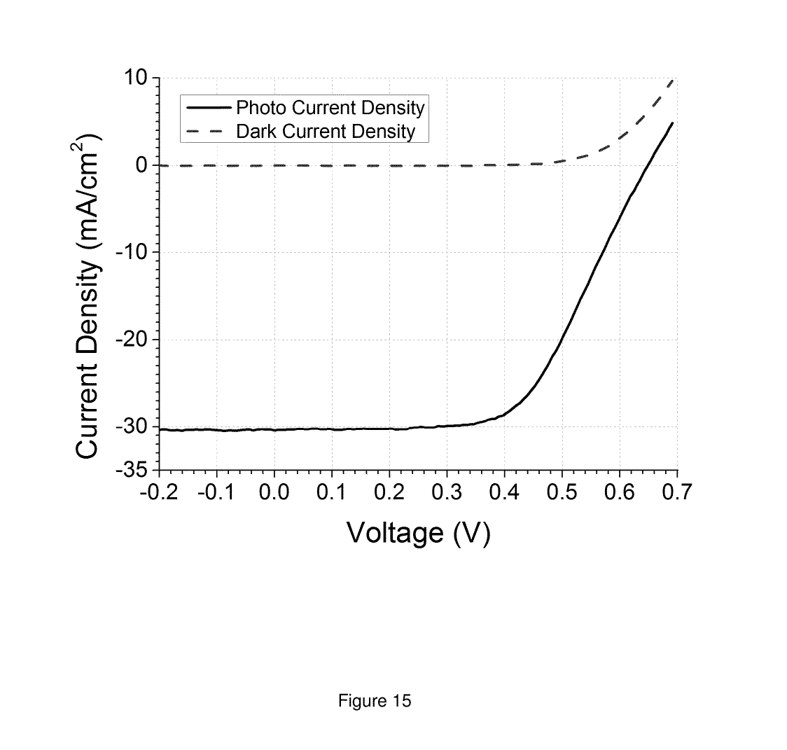

With reference to FIG. 15, cell performance results are provided for a cell fabricated according to the unifacial embodiment shown in FIG. 2(b). The cells were fabricated on a 280 μm thick double-side polished (100) 1-5Ωcm n-type silicon wafer. The native oxide-SiNx passivation layers were grown in a manner similar to that described above for the back amorphous-crystalline silicon heterojunction PV solar cell. A grid pitch of 80 μm and grid width of 4 μm was used for the 1 cm² cells. Doped amorphous silicon was deposited in the selectively opened regions/lines of the passivation layers followed by deposition of the Cr—Ag metal layers. For the unifacial cell, the entire back surface was also metallized.

As shown in FIG. 15, a cell efficiency of 11.6% is obtained for native oxide-SiNx passivated unifacial device with V_{OC} of 649 mV, J_{SC} of 30.3 mA/cm² and fill-factor of 0.60 for a 1 cm² untextured cell. All measurements having been performed under AM 1.5 global spectrum illumination.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

### REFERENCES

[1] M. M. Atalla, E. Tannenbaum, and E. J. Scheibner. Stabilization of silicon surfaces by thermally grown oxides. The Bell System Technical Journal, 38:749-783, 1959.
[2] D. Khang and N. J. Plainfield. Electric field controlled semiconductor device. U.S. Pat. No. 3,102,230, 1960.
[3] H.-U. Schreiber and E. Froschle. High quality rf-sputtered silicon dioxide layers. Journal of Electrochemical Society, 123:30-33, 1976.
[4] T. Serikawa and T. Yachi. Magnetron-sputtered SiO2 films in hydrogen-argon mixtures. Journal of Electrochemical Society, 131:2105-2109, 1985.
[5] K. Eljabaly and A. Reisman. Growth kinetics and annealing studies of the ‘cathodic’ plasma oxidation of silicon. Journal of Electrochemical Society, 138:1064-1070, 1991.
[6] K. H. Lee, W. H. Liu, and S. A. Campbell. Growth kinetics and electrical characteristics of thermal silicon dioxide grown at low temperatures. Journal of Electrochemical Society, 140:501-505, 1993.
[7] J. Batey and E. Tierney. Low temperature deposition of high quality silicon dioxide by plasma enhanced chemical vapor deposition', Journal of Applied Physics, 60: 3136-3145, 1986.
[8] Y. Kawai, N. Konishi, J. Watanabe, and T. Ohmi. Ultra-low-temperature growth of high-integrity gate oxide-films by low-energy ion-assisted oxidation. Applied Physics Letters, 64:2223-2225, 1994.
[9] M. A. Green. The path to 25% silicon solar cell efficiency: History of silicon cell evolution. Progress in Photovoltaics: Research and Application, 17:183-189, 2009.
[10] M. Taguchi, Mikio Taguchi, H. Sakata, and E. Maruyama. Development status of high-efficiency hit solar cells. Solar Energy Materials & Solar Cells, 95(1):18-21, 2011.
[11] U. Rau, N. Jensen, and J. H. Werner. Low cost, high volume production of >22% efficiency silicon solar cells. Proceedings of the 22nd European Photovoltaic Solar Energy Conference, Milan, Italy., pages 816-819, 2007.
[12] C Leguijt, P. Lölgen, J. A. Eikelboom, P. H. Amesz, R. A. Steeman, W. C. Sinke, P. M. Sarro, L. A. Verhoef, P. P. Michiels, Z. H. Chen, and A. Rohatgi. Very-low surface recombination velocities on 2.5Ω -cm Si wafers, obtained with low temperature PECVD of Si-oxide and Si-nitride. Solar Energy Material and Solar Cells, 34:177-181, 1994.
[13] Z. Chen, A. Rohatgi, and D. Ruby. Silicon surface and bulk defect passivation by low temperature PECVD oxides and nitrides. The Conference Record of the First WCPEC, Waikoloa, Hawaii., pages 1331-1334, 1994.
[14] Thomas Lauinger, Jan Schmidt, Armin G. Aberle, and Rudolf Hezel. Record low surface recombination velocities on 1Ω-cm p-silicon using remote plasma silicon nitride passivation. Applied Physics Letters, 68(9):1232-1234, 1996.
[15] J Schmidt and M Kerr. Highest-quality surface passivation of low-resistivity p-type silicon using stoichiometric PECVD silicon nitride. Solar Energy Materials and Solar Cells, 65 (1-4):585-591, 2001.
[16] H. Mäckel and R. Lüdemann. Detailed study of the composition of hydrogenated SiNx layers for high-quality silicon surface passivation. Journal of Applied Physics, 92(5):2602-2609,2002.
[18] I. Martin, M. Vetter, A. Orpella, J. Puigdollers, A. Cuevas, and R. Alcubilla. Surface passivation of p-type crystalline Si by plasma enhanced chemical vapor deposited amorphous SiCx:H films. Applied Physics Letters, 79(14):2199-2201, 2001.
[19] W. L. Warren, J. Kanicki, J. Robertson, E. H. Poindexter, and P. J. McWhorter. Electron paramagnetic resonance investigation of charge trapping centers in amorphous silicon nitride films. Journal of Applied Physics, 74(6):4034-4046, 1993.
[20] G. Dingemans, M. M. Mandoc, S. Bordihn, M. C. M. van de Sanden, and W. M. M. Kessels. Effective passivation of Si surfaces by plasma deposited SiOx/a-SiNx:H stacks. Applied Physics Letters, 98:222102, 2011.
[21] Stefan Dauwe, Lutz Mittelstädt, Axel Metz, and Rudolf Hezel. Experimental evidence of parasitic shunting in silicon nitride rear surface passivated solar cells. Progress in Photovoltaics: Research and Application, 10:271-278, 2002.
[22] J Schmidt, M Kerr, and A Cuevas. Surface passivation of silicon solar cells using plasma-enhanced chemical-vapour-deposited SiN films and thin thermal SiO2/plasma SiN stacks. Semiconductor Science and Technology, 16(3):164-170, 2001.
[23] S. Narasimha and A. Rohatgi. Effective passivation of the low resistivity silicon surface by a rapid thermal oxide plasma silicon nitride stack. Applied Physics Letters, 72(15):1872-1874, 1998.
[24] Y. Larionova, V. Mertens, N.-P. Harder, and R. Brendel. Surface passivation of n-type czochralski silicon substrates by thermal-SiO2/plasma-enhanced chemical vapor deposition SiN stacks. Applied Physics Letters, 96:032105, 2010.
[25] Marc Hofmann, Stefan Janz, Christian Schmidt, Stephan Kambor, DominikSuwito, Norbert Kohn, JochenRentsch, Ralf Preu, and Stefan W Glunz. Surface passivation of silicon solar cells using plasma-enhanced chemical-vapour-deposited SiN films and thin thermal SiO2/plasma SiN stacks. Solar Energy Materials and Solar Cells, 93(6-7):1074-1078, 2009.
[26] F. Masuoka and H. Iizuka. Semiconductor memory device and method for manufacturing the same. U.S. Pat. No. 4,531,203, 1985.
[27] Sara Olibet, EvelyneVallat-Sauvain, and Christophe Ballif. Model for a-Si:H/c-Si interface recombination based on the amphoteric nature of silicon dangling bonds. Physical Review B, 76:035326, 2007.
[28] Barzin Bahardoust, Alongkarn Chutinan, Keith Leong, Adel B. Gougam, Davit Yeghikyan, Tome Kosteski, Nazir P. Kherani, and Stefan Zukotynski. Passivation study of the amorphous-crystalline silicon interface formed using DC saddle-field glow discharge. Physica Status Solidi A, 207(3):539-543, 2010.
[29] J. D. Plummer, M. D. Deal, and P. B. Griffin. Silicon VLSI Technology Fundamentals, Practice and Modeling. Prentice Hall: Englewood Cliffs, New Jersery, 2000.
[30] Ronald A. Sinton and Andres Cuevas. Contactless determination of current-voltage characteristics and minority carrier lifetimes in semiconductors from quasi-steady-state photo-conductance data. Applied Physics Letters, 69(17):2510-2512, 1996.
[31] M. Morita, T. Ohmi, E. Hasegawa, M. Kawakami, and M. Ohwada. Growth of native oxide on a silicon surface. Journal of Applied Physics, 68(3):1272-1281, 1990.
[32] A. Hertanto, H. Liu, D. Yeghikyan, B. G. Rayaprol, N. P. Kherani, and S. Zukotynski. Back amorphous-crystalline silicon heterojunction (BACH) photovoltaic device. IEEE 34th PVSC, 2009.

Therefore what is claimed is:

1. A method of passivating a crystalline silicon surface, the method comprising:
cleaning the silicon surface and removing a pre-existing native oxide layer;
performing a low temperature oxide growth process to form an ultra-thin silicon oxide layer on the silicon surface; and
performing a low temperature depositing process to deposit a passivating dielectric layer on the ultra-thin silicon oxide layer.

2. The method according to claim 1 wherein the ultra-thin silicon oxide layer has a thickness less than approximately 100 Angstroms.

3. The method according to claim 1 wherein the ultra-thin silicon oxide layer has a thickness less than approximately 15 Angstroms.

4. The method according to claim 1 wherein the ultra-thin silicon oxide layer has a thickness less than approximately 10 Angstroms.

5. The method according to claim 1 wherein the low temperature depositing process and the low temperature oxide growth process are performed at temperatures below approximately 500 degrees Celsius.

6. The method according to claim 1 wherein the low temperature oxide growth process is performed under ambient conditions such that the ultra-thin silicon oxide layer is a native oxide layer.

7. The method according to claim 6 wherein the native oxide layer is formed over a time duration exceeding 50,000 minutes.

8. The method according to claim 6 wherein the native oxide layer is formed over a time duration exceeding 100,000 minutes.

9. The method according to claim 6 wherein the native oxide layer is formed over a time duration exceeding 150,000 minutes.

10. The method according to claim 6 including controlling humidity during the formation of the native oxide layer.

11. The method according to claim 1 wherein the low temperature oxide growth process is performed in an oxidizing environment.

12. The method according to claim 11 wherein the low temperature oxide growth process is performed in the presence of ozone.

13. The method according to claim 1 wherein the low temperature oxide growth process is performed by chemically oxidizing the silicon surface.

14. The method according to claim 13 wherein a chemical oxidizing agent is selected from the group consisting of a solution of H2SO4 and H2O2, a solution of HNO3, and a solution of H2O2.

15. The method according to claim 1 wherein the low temperature oxide growth process includes providing oxygen ions from catalytic dissociation of oxygen or hot-wire dissociation of oxygen.

16. The method according to claim 1 wherein the passivating dielectric layer is formed by a plasma enhanced chemical deposition process.

17. The method according to claim 16 wherein the plasma enhanced chemical deposition process is performed at one or more temperatures within the range of approximately ambient to 400 degrees C.

18. The method according to claim 16 wherein the plasma enhanced chemical deposition process is performed at one or more temperatures within the range of approximately 400 degrees C. to approximately 800 degrees C.

19. The method according to claim 16 wherein the plasma enhanced chemical deposition process is performed at one or more temperatures greater than approximately 800 degrees C.

20. The method according to claim 16 wherein the plasma enhanced chemical deposition process is based on one or more hydrogen-containing precursor gases.

21. The method according to claim 1 wherein the passivating dielectric layer is silicon nitride (SiNx).

22. The method according to claim 1 wherein the passivating dielectric layer includes a silicon-based oxide material.

23. The method according to claim 1 wherein the passivating dielectric layer includes a non-silicon based oxide material.

24. The method according to claim 1 wherein the passivating dielectric layer includes a material selected from the group consisting of include PECVD silicon nitride alloys, PECVD silicon oxynitride alloys, PECVD silicon carbide alloys, PECVD hydrogenated amorphous silicon alloys.

25. The method according to claim 1 wherein the passivating dielectric layer is a semiconductor having dielectric properties.

26. The method according to claim 25 wherein the semiconductor is amorphous silicon or hydrogenated amorphous silicon.

27. The method according to claim 1 wherein the passivating dielectric layer is doped.

28. The method according to claim 1 wherein the passivating dielectric layer has a thickness of between approximately 10 nm and 100 nm.

29. The method according to claim 1 further including depositing one or more additional dielectric layers on the passivating dielectric layer.

30. The method according to claim 1 further comprising:
depositing a layer of a first doped material over a first region of the passivating dielectric layer;
depositing a layer of a second doped material over a second region of the passivating dielectric layer;
performing a suitable firing process in order to form a p-type hetero-/homo-junction with the crystalline silicon surface over the first region and an n-type hetero-/homo-junction with the crystalline silicon surface over the second region;
forming suitable electrical contacts at the first region and the second region;
wherein the first region and the second region are suitably spaced to form a semiconductor device.

31. The method according to claim 30 wherein one or more of the first doped material and the second doped material is deposited by ink jet printing or silk screen printing.

32. The method according to claim 30 wherein the semiconductor device is selected from the group consisting of a photovoltaic cell, a MOSFET device, and a flash memory device.

33. A semiconductor structure having a passivated silicon surface, semiconductor structure comprising:
a substrate including a crystalline silicon layer;
a silicon oxide layer provided on at least a portion of a surface of said silicon layer, wherein said silicon oxide layer has a thickness less than approximately 15 Angstroms; and
a passivating dielectric layer provided on said silicon oxide layer.

34. The semiconductor structure according to claim 33 wherein said silicon oxide layer has a thickness less than approximately 10 Angstroms.

35. The semiconductor structure according to claim 33 wherein one or more of said silicon oxide layer and said passivating dielectric layer includes hydrogen.

36. The semiconductor structure according to claim 33 wherein said passivating dielectric layer is silicon nitride (SiNx).

37. The semiconductor structure according to claim 33 wherein said passivating dielectric layer includes a silicon-based oxide material.

38. The semiconductor structure according to claim 33 wherein said passivating dielectric layer includes a non-silicon based oxide material.

39. The semiconductor structure according to claim 33 wherein said passivating dielectric layer includes a material selected from the group consisting of include PECVD silicon nitride alloys, PECVD silicon oxynitride alloys, PECVD silicon carbide alloys, PECVD hydrogenated amorphous silicon alloys.

40. The semiconductor structure according to claim 33 further including one or more additional dielectric layers on said passivating dielectric layer.

41. The semiconductor structure according to claim 33 wherein said surface is a textured surface configured for optical trapping.

42. The semiconductor structure according to claim 33 wherein said silicon layer is a polycrystalline silicon layer.

43. The semiconductor structure according to claim 33 wherein said silicon layer is characterized by a surface recombination velocity of less than approximately 10 cm/s.

44. The semiconductor structure according to claim 33 wherein said silicon layer is characterized by a carrier lifetime of approximately 1 millisecond.

45. The semiconductor structure according to claim 33 wherein said substrate is a flexible thin silicon film having a thickness less than approximately 50 microns.

46. The semiconductor structure according to claim 33 having a photovoltaic cell formed therein, wherein said silicon layer is an optical absorbing layer of said photovoltaic cell.

47. The semiconductor structure according to claim 33 further comprising:
a first doped amorphous silicon layer contacting said crystalline silicon layer through a first opening formed in said passivating dielectric layer and in said silicon oxide layer, said first doped amorphous silicon layer forming a p-type heterojunction with said crystalline silicon layer; and
a second doped amorphous silicon layer contacting said crystalline silicon layer through a second opening formed in said passivating dielectric layer and in said silicon oxide layer, said second doped amorphous silicon layer forming an n-type heterojunction with said crystalline silicon layer;
a first electrical contact layer formed on said first doped amorphous silicon layer; and
a second electrical contact layer formed on said second doped amorphous silicon layer;
wherein said first doped amorphous silicon layer and said second doped amorphous silicon layer are suitably spaced to form a photovoltaic cell.

48. The semiconductor structure according to claim 47 wherein said first doped amorphous silicon layer and said second doped amorphous silicon layer are formed on a common surface of said crystalline silicon layer.

49. The semiconductor structure according to claim 47 wherein said first doped amorphous silicon layer and said second doped amorphous silicon layer are formed on opposing surfaces of said crystalline silicon layer.

50. The semiconductor structure according to claim 49 wherein said first electrical contact layer and said second electrical contact layer are provided such light may enter said photovoltaic cell from both sides thereof.

51. The semiconductor structure according to claim 49 wherein one of said first electrical contact layer and said second electrical contact layer forms an electrically conductive coating over one surface of said semiconductor structure, such that light may enter said photovoltaic cell from one side thereof.

52. The semiconductor structure according to claim 47 wherein said first doped amorphous silicon layer and said second doped amorphous silicon layer are hydrogenated amorphous silicon layers.

53. The semiconductor structure according to claim 33 having an MOSFET device formed therein, wherein said MOSFET device includes said silicon layer.

54. The semiconductor structure according to claim 33 having a flash memory device formed therein, wherein said flash memory device includes said silicon layer.

55. The semiconductor structure according to claim 45 wherein said substrate includes a plurality of electronic devices, and wherein said semiconductor structure further includes:
one or more additional substrates, wherein each additional substrate is a flexible thin silicon film having a thickness less than approximately 50 microns, and wherein each additional substrate includes a plurality of electronic devices; and
at least one spacer separating adjacent substrates, such that a gap is provided between adjacent substrates;
wherein said gap is suitable for active or passive cooling of said electronic devices.

56. The semiconductor structure according to claim 55 wherein said gap is filled with a thermally conductive material.

57. The semiconductor structure according to claim 56 wherein said thermally conductive material is in thermal communication with an external heat sink.
